(19) United States
(12) Patent Application Publication
(10) Pub. No.: US 2005/0151251 A1
(43) Pub. Date: Jul. 14, 2005

(54) Mounting substrate and electronic component using the same

(75) Inventors: Takuya Adachi, Tokyo (JP); Kenji Inoue, Tokyo (JP)

Correspondence Address: OLIFF & BERRIDGE, PLC, P.O. BOX 19928, ALEXANDRIA, VA, 22320, US

(73) Assignee: TDK CORPORATION, Chuo-ku (JP)

(21) Appl. No.: 11/013,698

(22) Filed: Dec. 17, 2004

(30) Foreign Application Priority Data
Dec. 19, 2003 (JP) 2003-422322

(51) Int. Cl. H01L 23/48

(52) U.S. Cl. 257/738; 257/778

(57) ABSTRACT

A mounting substrate of an embodiment of the present invention comprises a first main surface constituting a mounting surface on which an electric device is mounted, and having formed thereon an electrode pattern comprising a plurality of electrode pads that are electrically connected to the electronic device via a bump, and a second main surface which is positioned on the opposite side of the first main surface, and which has formed thereon a plurality of input/output terminals that are electrically connected to the electrode pads. All of the input/output terminals are formed in positions apart from the periphery of the mounting substrate.

### BACKGROUND OF THE INVENTION

1. Field of the Invention

The present invention relates to a mounting substrate, and to an electronic component using the same.

2. Related Background of the Invention

Today, miniaturization of the mobile communication apparatus typified by the remarkably spreading cellular phones has been developing progressively. With this miniaturization, further miniaturization of the electronic components used in the mobile communication apparatus has been demanded.

For this reason, in a conventional electronic component 100, as shown in FIG. 6, an electronic device 20 in which a circuit element is formed on a device substrate is mounted on a mounting substrate 14 in a face-down manner through a bump 21. The electronic component 100 is constituted by sealing this electronic device 20 by mean of a sealing portion 22, such as a cap or resin.

In the prior art, an electrode 30 is disposed on a side surface of the mounting substrate 14 which has a laminated structure, and an electrode pad P to which the electronic device 20 is connected, a conductive pattern formed between the layers, and an input/output terminal S are connected via the electrode 30.

Note that the electronic component with such a structure is disclosed in, for example, Japanese Patent Application Laid-Open No. 2003-249840.

### SUMMARY OF THE INVENTION

When mounting the electronic component 100 having the above structure onto an external connection substrate 24, a wraparound of a fillet 23 occurs on the electrode 30 formed on the side surface of the mounting substrate 14, and as a result, a mounting region R of the electronic component 100 in the external connection substrate 24 becomes larger than the size of the electronic component 100, as shown in FIG. 7 and FIG. 8.

Further, the fillet 23, input/output terminal S, and a fitting pattern on the mounting substrate 14 side are causes of generation of parasitic components, such as a parasitic capacitance and parasitic inductance. Therefore, especially in the case where the electronic device 20 is a high frequency device, the characteristics thereof may be deteriorated.

Furthermore, in such a structure where the electrode 30 is formed on the side surface of the mounting substrate 14, as shown in FIG. 9 and FIG. 10, the input/output terminal S straddles cutting lines L in a collective substrate (see (b) in FIG. 9 and (b) in FIG. 10) prior to being separated by cutting it into individual pieces of the mounting substrate 14 (see (a) in FIG. 9 and (a) in FIG. 10), in order to form the electrode 30 and the electrode pad P or input/output terminal S in a continuous fashion. Consequently, if the position of the electrode pattern or cut position is moved a little way off the right position, the area of the input/output terminal S in the separated mounting substrate 14 becomes different individually. Therefore, especially in the case where the electronic device 20 is a high frequency device, even if the characteristics of the electronic devices 20 are equalized, the characteristics become inhomogeneous by mounting the electronic device 20 onto the mounting substrate 14. The same problem occurs even when an interlayer pattern 27 straddles the cutting lines L, as shown in FIG. 11. Note that, in FIG. 11 as well, (a) indicates the individual piece, and (b) indicates the collective substrate prior to being cut into the individual pieces.

When the input/output terminal S ends at the cutting line L, as shown in FIG. 10, even if cut position is moved a little way off the right position, a defect of wire breakage occurs. Therefore, in order to avoid such a defect, it is necessary to have a complex pattern configuration in which the pattern is rotated 180 degrees around for each line, which provides no freedom of pattern formation. In FIG. 12 as well, (a) indicates the individual piece, and (b) indicates the collective substrate prior to being cut into the individual pieces. Further in FIG. 12, the individual pieces provided in line in a region C have the patterns rotated 180 degrees around with respect to the patterns of individual pieces arranged in line in an adjacent region.

Therefore, an object of the present invention is to provide a mounting substrate which can reduce the mounting area when being mounted on an external connection substrate, and an electronic component using this mounting substrate.

Further, an object of the present invention is to provide a mounting substrate capable of reducing characteristic deterioration caused by generation of parasitic components, and an electronic component using this mounting substrate.

Furthermore, an object of the present invention is to provide a mounting substrate capable of achieving uniformity of the area of the external connection terminal between the mounting substrates, and an electronic component using this mounting substrate.

A first mounting substrate according to the present invention comprises a first main surface constituting a mounting surface on which an electronic device is mounted, and being formed thereon an electrode pattern comprising a plurality of electrode pads that are electrically connected to the electronic device through electrical connection means, and a second main surface which is positioned on the opposite side of the first main surface, and which has formed thereon a plurality of external connection terminals that are electrically connected to the electrode pads, wherein all of the external connection terminals being formed in positions apart from a periphery of the mounting substrate.

A second mounting substrate of the present invention is the above mentioned first mounting substrate wherein the electrode pattern is formed in a position apart from the periphery of the mounting substrate.

A third mounting substrate of the present invention is the above mentioned first or second mounting substrate wherein the mounting substrate is constituted with stacked substrates in which a predetermined conductive pattern is formed between layers, and the conductive pattern is formed in a position apart from the periphery of the mounting substrate.

A first electronic component according to the present invention comprises an electronic device in which a predetermined circuit element is formed on a device substrate, any one of the first to third mounting substrates in which the electronic device is connected to the electrode pads via the electrical connection means and is mounted on the first main surface, and sealing means for sealing the electronic device.

A second electronic component according to the present invention is the first electronic component further comprising an external connection substrate. This external connection substrate has a main surface for mounting the mounting substrate. The main surface of the external connection substrate comprises a first region and a second region. The first region faces the external connection terminal. The second region surrounds the first region. The first region is provided with a terminal that is connected to the external connection terminal via an electrical connection member.

A third electronic component according to the present invention is the second electronic component wherein the electrical connection member is a solder, and the second region is provided with a solder resist.

A fourth electronic component according to the present invention is any one of the first to third electronic components wherein the electronic device is a piezoelectric resonator for obtaining a signal with a predetermined resonance frequency by bulk waves propagating inside a piezoelectric film, or a surface acoustic wave resonator for obtaining a signal with a predetermined resonance frequency by surface acoustic waves propagating on the surface of a piezoelectric.

A fifth electronic component of the present invention is any one of the first to fourth electronic components wherein the electrical connection means is a bump or a bonding wire.

### BRIEF DESCRIPTION OF THE DRAWINGS

FIG. 1 is a cross sectional view showing an electronic component of an embodiment of the present invention;

FIG. 2 is a bottom view showing a mounting substrate constituting the electronic component of FIG. 1;

FIG. 3 is a cross sectional view showing a state in which the electronic component of FIG. 1 is mounted on an external connection substrate;

FIG. 4 is an explanatory drawing showing a mounting substrate which is a separated individual piece constituting the electronic component of FIG. 1, and a collective substrate prior to being separated, along with a forming position of an external connection terminal;

FIG. 5 is an explanatory drawing showing the mounting substrate which is a separated individual piece constituting the electronic component of FIG. 1, and a collective substrate prior to being separated, along with a forming position of an interlayer pattern;

FIG. 6 is a cross sectional view showing a conventional electronic component;

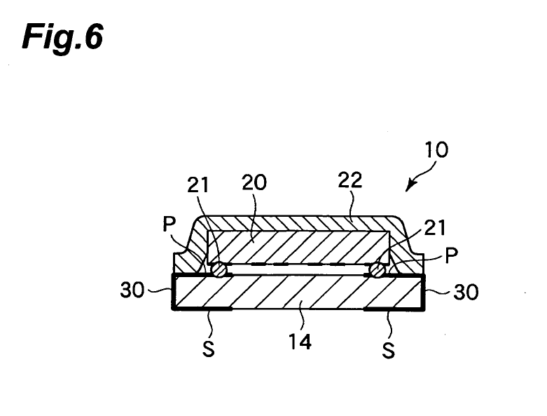

FIG. 7 is a bottom view showing a mounting substrate constituting the electronic component of FIG. 6;

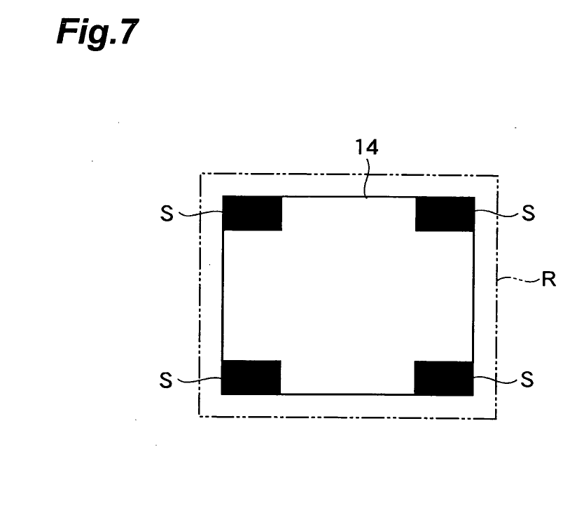

FIG. 8 is a cross sectional view showing the state in which the electronic component of FIG. 6 is mounted on the external connection substrate;

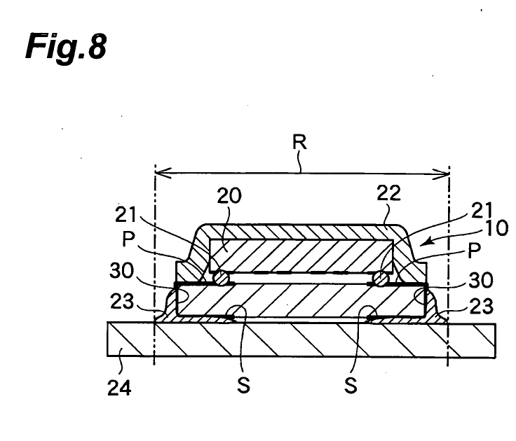

FIG. 9 is an explanatory drawing showing conventional examples of a mounting substrate which is a separated individual piece, and a collective substrate prior to being separated, along with a forming position of the external connection terminal;

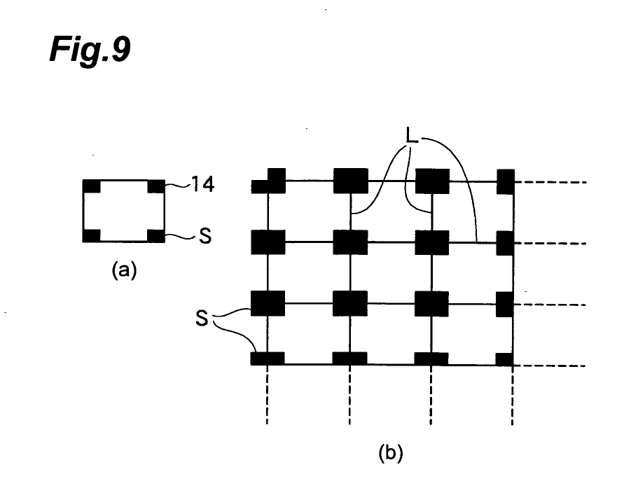

FIG. 10 is an explanatory drawing showing other conventional examples of the mounting substrate which is a separated individual piece, and a collective substrate prior to being separated, along with a forming position of the external connection terminal;

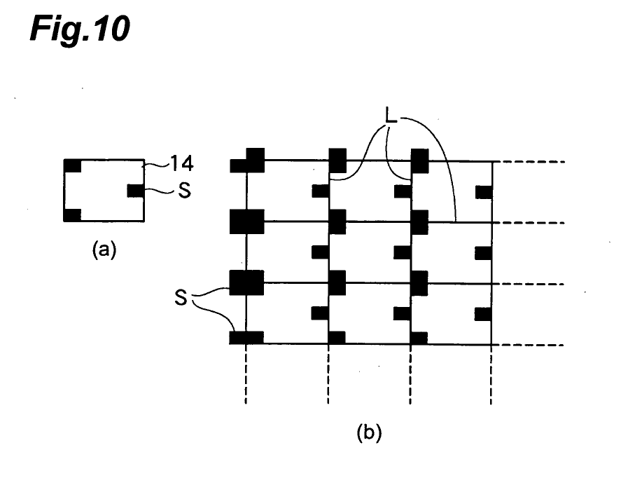

FIG. 11 is an explanatory drawing showing conventional examples of the mounting substrate which is a separated individual piece, and a collective substrate prior to being separated, along with a forming position of an interlayer pattern;

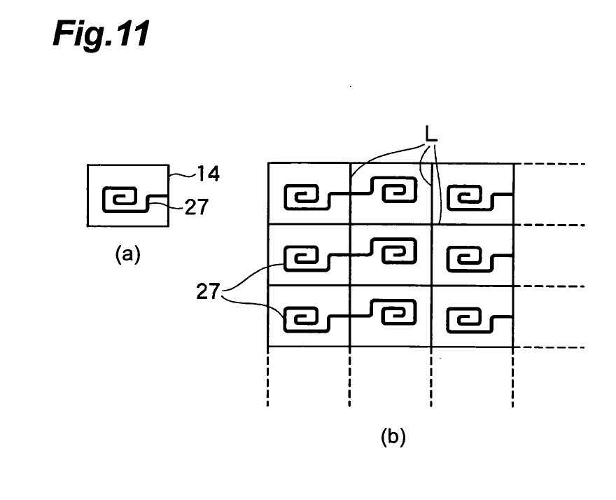

FIG. 12 is an explanatory drawing showing further conventional examples of the mounting substrate which is a separated individual piece, and a collective substrate prior to being separated, along with a forming position of the external connection terminal; and

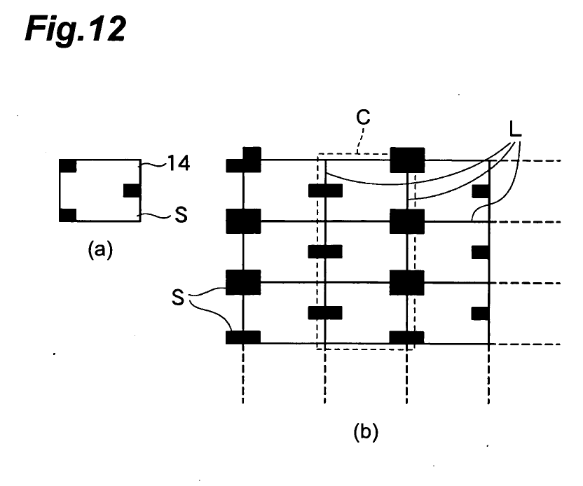

FIG. 13 is a cross sectional view showing an electronic component comprising the electronic component shown in FIG. 1 and the external connection substrate.

### DESCRIPTION OF THE PREFERRED EMBODIMENTS

The best mode for carrying out the present invention will now be described in more detail hereinbelow with reference to the drawings. The same members will be denoted by the same reference symbols throughout the accompanying drawings, without redundant description. It is noted that the description herein concerns the best mode for carrying out the present invention and that the present invention is by no means intended to be limited to the mode.

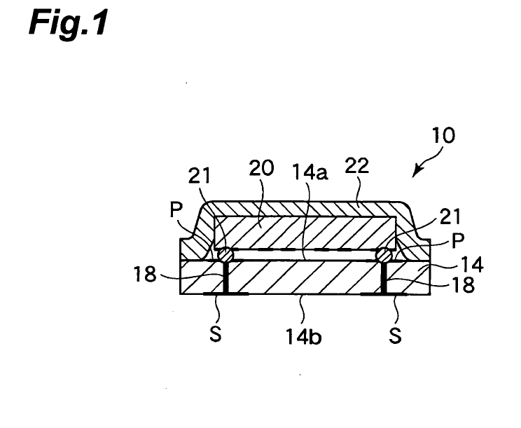

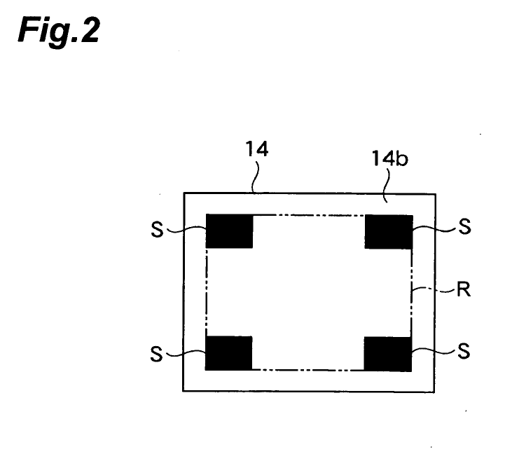

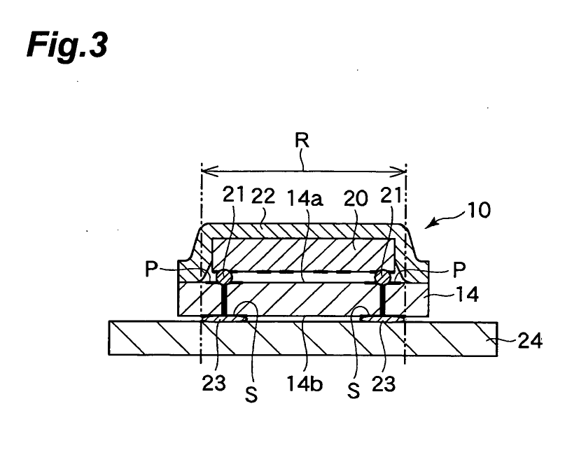

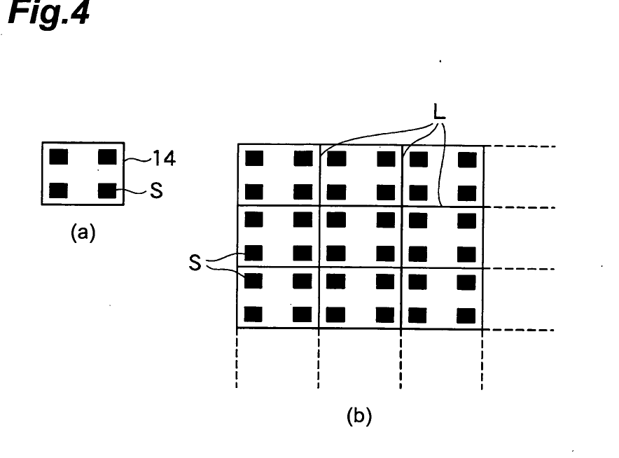

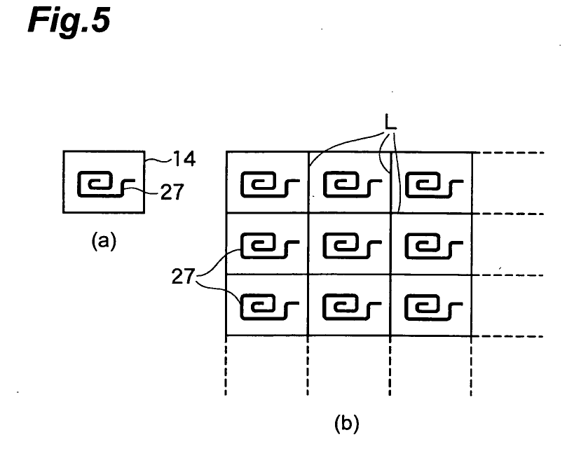

FIG. 1 is a cross sectional view showing an electronic component of an embodiment of the present invention, FIG. 2 is a bottom view showing a mounting substrate constituting the electronic component of FIG. 1, FIG. 3 is a cross sectional view showing a state in which the electronic component of FIG. 1 is mounted on an external connection substrate, FIG. 4 is an explanatory drawing showing a mounting substrate which is a separated individual piece constituting the electronic component of FIG. 1, and a collective substrate prior to being separated, along with a forming position of an external connection terminal, and FIG. 5 is an explanatory drawing showing the mounting substrate which is a separated individual piece constituting the electronic component of FIG. 1, and a collective substrates prior to being separated, along with a forming position of an interlayer pattern. Note that, in FIG. 4, (a) indicates a bottom face of the mounting substrate which turned into an individual chip, and (b) indicates a bottom face of the collective substrate prior to being separated into the individual pieces. Further, in FIG. 5, (a) indicates a bottom face of the mounting substrate which turned into an individual chip, and (b) indicates a bottom surface of the collective substrate prior to being separated into individual pieces.

An electronic component 10 shown in FIG. 1 has a mounting substrate 14 and a resonator (electronic device) 20 mounted on the mounting substrate 14. This resonator 20 is a piezoelectric resonator which can obtain a signal with a predetermined resonance frequency by bulk waves propagating inside a piezoelectric film through a piezoelectric effect caused by applying an AC voltage to a lower electrode and an upper electrode, which are not shown. Note that a surface acoustic wave resonator for obtaining a signal with a predetermined resonance frequency by surface acoustic waves propagating on the surface of a piezoelectric, or other device can be applied as the electronic device.

A first main surface 14a of the mounting substrate 14 constitutes a mounting surface on which the resonator 20 is mounted. An electrode pattern comprising a plurality of electrode pads P is formed on the first main surface 14a. Bumps (electrical connection means) 21, such as stud bumps or plating bumps, are formed on the electrode of the above mentioned resonator 20. The bumps 21 are connected to the electrode pads P of the mounting substrate 14. Therefore, the resonator 20 is mounted on the first main surface 14a of the mounting substrate 14 by means of face-down bonding. Note that the electrode pattern is formed by means of printing or etching. Further, the resonator 20 and the mounting substrate 14 may be connected by a bonding wire (electrical connection means).

In the mounting substrate 14, an input/output terminal (external connection terminal) S is formed on a second main surface 14b positioned to the opposite side of the first main surface 14a, and the resonator 20 is mounted on the first main surface 14a as described above. Further, there is formed in the mounting substrate 14 an electrode 18 formed by a conductor material disposed inside an hole, one end of which is opened at the second main surface 14b and the other end of which is opened at the first main surface 14a. Note that a ground terminal (not shown) is also provide on the second main surface 14b, as shown in FIG. 1.

The resonator 20 mounted on the mounting substrate 14 is sealed by a resin (sealing means) 22 which is applied, thereby having a chip-size package (CSP) structure. As means for sealing the resonator 20, a cap can be used instead of the resin to hermetically seal the resonator 20.

As shown in FIG. 2 in detail, the input/output terminals S formed on the second main surface 14b are disposed in positions such that all of the input/output terminals S are placed apart from a periphery of the mounting substrate 14.

The electrode pattern comprising the electrode pads formed on the first main surface 14a of the mounting substrate 14 is also formed in a position apart from the periphery of the mounting substrate 14. Further, in the present embodiment, the mounting substrate 14 is constituted with a stacked substrate in which a predetermined conductive pattern, i.e. an interlayer pattern 27 (FIG. 5), is formed between the layers. The interlayer pattern 27 is also formed in a position apart from the periphery of the mounting substrate 14. However, the mounting substrate 14 may not necessary have the stacked structure.

It is only necessary that the all of the input/output terminals S be formed in positions apart from the periphery of the mounting substrate 14, and even the electrode pattern comprising the electrode pads P and the interlayer pattern 27 are not necessarily formed in positions apart from the periphery of the mounting substrates 14.

As described above, the input/output terminals S are formed in positions apart from the periphery of the mounting substrate 14 in the present embodiment, thus, as shown in FIG. 2 and FIG. 3, when mounting the electronic component 10 on the external connection substrate 24 with having the fillet 23 interposed therebetween, the mounting region R on the external connection substrate 24 side is a region surrounded by the input/output terminals S. As a result, it is possible to reduce the mounting area in the case where the electrode component 10 is mounted on the external connection substrate 24, and to enlarge a wiring space of the external connection substrate 24. Moreover, high density mounting of the electronic component 10 becomes possible.

In addition, since there is no electrode formed on a side surface of the mounting substrate 14, the fillet 23, which is a cause of parasitic component, does not wrap around to the side surface of the mounting substrate 14 even when mounting on the external connection substrate 24, thus it is possible to reduce characteristic deterioration caused by generation of parasitic components, such as a parasitic capacitance and parasitic inductance.

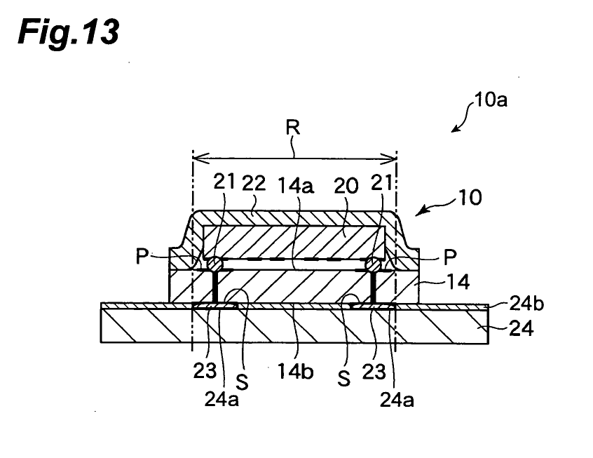

FIG. 13 is a cross sectional view showing an electronic component comprising the electronic component shown in FIG. 1 and the external connection substrate. An electronic component 10a shown in FIG. 13 comprises an electronic component 10 shown in FIG. 1 and the external connection substrate 24.

As shown in FIG. 13, the external connection substrate 24 comprises a first region and a second region on a main surface thereof for mounting the electronic component 10. The first region is a region that faces the input/output terminals S. In the first region, a wiring pattern is partially exposed as a terminal 24a. The terminal 24a is electrically connected to the input/output terminal S through the fillets 23.

The second region is a region that surrounds the first region. The second region is a region for preventing the fillet (electrical connection member) 23 from outflowing. In the present embodiment, the second region is provided with a solder resist 24b. Note that the solder resist 24b is not necessarily provided on the entire surface of the main surface excluding the first region. Therefore, it is only necessary that the solder resist 24b be provided in a position that is necessary for preventing the fillet 23 from outflowing.

According to the external connection substrate 24, outflow of the fillet 23 can be further prevented by the solder resist 24b provided in the second region. Therefore, the density mounting of the electronic component 10 can be further raised. Moreover, the characteristics of the electronic component 10 can be further improved.

FIG. 4 shows the mounting substrate 14 which is a separated individual piece, and the collective substrate prior to being separated, along with a forming position of the input/output terminal S. FIG. 5 shows the mounting substrate 14 which is a separated individual piece, and the collective substrate prior to being separated, along with a forming position of the interlayer pattern 27.

As described above, the electrode patterns including the input/output terminals S, interlayer patterns 27 and electrode pads P are formed in a position apart from the periphery of the mounting substrate 14. Therefore, in the collective substrate prior to being separated into individual pieces, i.e. the mounting substrate 14, the input/output terminal S and the like are disposed inside the cutting lines L (for example, 50 μm or more inside) that form the contour of the substrate. The distance between the cutting line L and input/output terminal S, or between the interlayer pattern 27 and electrode pattern may be set appropriately in accordance with printing precision of the pattern, precision or the reduction ratio of lamination of the multi-layer substrate, and precision of a cutting machine such as a dicer or knife; however it is not limited to such a numerical value as 50 μm or more.

In this manner, by disposing the electrode patterns including the input/output terminal S, interlayer pattern 27 and electrode pad P inside the cutting lines L in the collective substrate, such that these patterns are positioned apart from the periphery of the mounting substrate 14, the patterns are not cut when cutting the collective substrates into individual pieces to create the mounting substrate 14. Therefore, it is possible to prevent variation in the dimensions caused by that the electrode pattern or cut position is moved a little way off the right position between the mounting substrates 14, whereby the areas of the electrode patterns including the input/output terminal S, interlayer pattern 27 and electrode pad P can be uniformed.

Further, by disposing the electrode patterns including the input/output terminal S, interlayer pattern 27 and electrode pad P inside the cutting lines L in the collective substrate, such that these patterns are positioned apart from the periphery of the mounting substrate 14, it is not necessary to take into consideration for symmetry of the adjacent patterns, thus not only the degree of freedom of design is increased, but also an easy pattern arrangement can be achieved.

As described in above preferred embodiments of the present invention, the following effects can be achieved according to the present invention.

Specifically, when mounting the mounting substrate on the external connection substrate with having the fillet interposed therebetween, the mounting region on the external connection substrate side becomes a region surrounded by the external connection terminals, thus it is possible to reduce the mounting area in the case where mounting the mounting substrate on the external connection substrate.

Furthermore, according to the present invention, since there is no electrode formed on the side surface of the mounting substrate, the fillet, which is a cause of parasitic components, does not wrap around to the side surface of the mounting substrate even when mounting the mounting substrate on the external connection substrate, thus it is possible to reduce characteristic deterioration caused by generation of such parasitic components as a parasitic capacitance and parasitic inductance.

Moreover, the patterns are not cut when cutting the collective substrate into individual pieces to create the mounting substrate. Therefore, it is possible to prevent variation in the dimension caused by that the electrode pattern or cut position is moved a little way off the right position between the mounting substrates, whereby the areas of the electrode patterns including the input/output terminal, interlayer pattern and electrode pad can be uniformed.

In addition, it is not necessary to take into consideration for symmetry of the adjacent patterns, thus not only the degree of freedom of design is increased, but also an easy pattern arrangement can be achieved.

1. A mounting substrate comprising:
a first main surface constituting a mounting surface on which an electric device is mounted, and being formed thereon an electrode pattern comprising a plurality of electrode pads which are electrically connected to the electronic device through electrical connection means; and
a second main surface which is positioned on the opposite side of the main surface, and which has formed thereon a plurality of external connection terminals that are electrically connected to the electrode pads,
wherein all of the external connection terminals are formed in positions apart from a periphery of the mounting substrate.

2. The mounting substrate according to claim 1, wherein the electrode pattern is formed in a position apart from the periphery of the mounting substrate.

3. The mounting substrate according to claim 1, wherein the mounting substrate is constituted with stacked substrates in which a predetermined conductive pattern is formed between layers, and the conductive pattern is formed in a position apart from the periphery of the mounting substrate.

4. An electronic component, comprising:
an electronic device in which a predetermined circuit element is formed on a device substrate;
the mounting substrate defined in claim 1 in which the electronic device is connected to the electrode pads via the electronic connection means and is mounted on the first main surface; and
sealing means for sealing said electronic device.

5. The electronic component according to claim 4 further comprising an external connection substrate having a main surface for mounting the mounting substrate,
wherein the main surface of the external connection substrate comprises a first region facing the external connection terminal and a second region surrounding the first region, and the first region is provided with a terminal electrically connected to the external connection terminal via an electrical connection member.

6. The electronic component according to claim 5, wherein the electrical connection member is a solder, and the second region is provided with a solder resist.

7. The electronic component according to claim 4, wherein the electronic device is a piezoelectric resonator for obtaining a signal with a predetermined resonance frequency by bulk waves propagating inside a piezoelectric film, or a surface acoustic wave resonator for obtaining a signal with a predetermined resonance frequency by surface acoustic waves propagating on the surface of a piezoelectric.

8. The electronic component according to claim 4, wherein said electrical connection means is a bump or a bonding wire.
